(19) United States
(12) Patent Application Publication
(10) Pub. No.: US 2024/0105537 A1
(43) Pub. Date: Mar. 28, 2024

(54) MOLD, LEAD FRAME, METHOD, AND ELECTRONIC DEVICE WITH EXPOSED DIE PAD PACKAGING

(71) Applicant: Texas Instruments Incorporated, Dallas, TX (US)

(72) Inventor: Makoto Shibuya, Tokyo (JP)

(21) Appl. No.: 17/953,410

(22) Filed: Sep. 27, 2022

(51) Int. Cl. H01L 23/31; H01L 21/56; H01L 23/495

(52) U.S. Cl. CPC H01L 23/3121; H01L 21/565; H01L 23/49503; H01L 23/49541

(57) ABSTRACT

An electronic device includes a semiconductor die attached to a die attach pad, a package structure having opposite first and second sides, opposite third and fourth sides spaced apart from one another along a first direction, and opposite fifth and sixth sides spaced apart from one another along an orthogonal second direction, conductive leads positioned along opposite third and fourth sides of the package structure, tie bars extending from the die attach pad and having respective ends exposed along the respective fifth and sixth sides of the package structure, and the fifth and sixth sides of the package structure each have individual indents that extend to a respective one of the third and fourth sides of the package structure.

### BACKGROUND

Integrated circuits (ICs) and other packaged electronic devices may include a metal die attach pad that supports a semiconductor die within a molded package structure. Exposing the bottom of the die attach pad can help improve heat dissipation and/or provide a ground reference connection to a host printed circuit board (PCB). However, leakage of molding compound can lead to over-molding during mold filling. This results in mold flash on the exposed bottom side of the die attach pad that can adversely affect the thermal and/or electrical performance in the finished electronic device. Providing a clampable tab at the ends of the die pad can help reduce over-molding, but this approach cannot be used with high density manufacturing designs that use column molding.

### SUMMARY

In one aspect, an electronic device includes a semiconductor die attached to a die attach pad, a package structure having leads opposite along opposite sides, and opposite ends with tie bars extending from the die attach pad and having respective ends exposed along the respective package ends, and the package structure ends have indents that extend to a respective one of the sides of the package structure.

In another aspect, a method of fabricating an electronic device includes engaging a first mold potion to bottom sides of die attach pads in respective unit areas of a lead frame panel array having rows and columns of the unit areas, engaging a second mold portion to lead bars between columns of the lead frame panel array with lobes of the second mold portion extending inwardly along column cavities of the second mold portion and engaging tie bars of the lead frame panel array between the unit areas, filling the column cavities of the second mold portion to form package structures along the column cavities of the second mold portion with indents of the package structures in corners of the unit areas of the lead frame panel array, trimming leads between columns of the lead frame panel array, and cutting through the tie bars between the unit areas along a row direction of the lead frame panel array to separate packaged electronic devices from the lead frame panel array.

In a further aspect, a lead frame panel array includes a contiguous metal structure that defines rows of unit areas along a first direction and columns of the unit areas along an orthogonal second direction, lead bars extending along the second direction between adjacent columns of the unit areas and connecting bars extending along the first direction from respective ones of the lead bars. Respective unit areas include a die attach pad, leads positioned along opposite sides of the die attach pad and spaced apart from the die attach pad along the first direction, the leads extending along the first direction from a respective one of the lead bars toward the die attach pad, and tie bars individually including a first portion that extends outward along the second direction from a respective corner of the die attach pad, and a second portion that extends from the first portion to a respective one of the connecting bars.

In another aspect, a mold includes a first mold potion configured to engage bottom sides of die attach pads in respective unit areas of a lead frame panel array having rows and columns of the unit areas, and a second mold portion configured to engage lead bars between columns of the lead frame panel array, the second mold portion including lobes extending inwardly along column cavities of the second mold portion and configured to engage tie bars of the lead frame panel array between the unit areas.

### BRIEF DESCRIPTION OF THE DRAWINGS

FIG. 1 is a top perspective view of an electronic device with angled tie bars extending from an exposed die attach pad and corner indents.

FIG. 1A is a bottom perspective view of the electronic device of FIG. 1.

FIG. 1B is another top perspective view of the electronic device of FIG. 1.

FIG. 1C is a bottom view of the electronic device of FIG. 1.

FIG. 2 is a flow diagram of a method of fabricating an electronic device.

FIG. 3 is a partial top plan view of a lead frame panel array.

FIG. 3A is a partial sectional side elevation view of the lead frame panel array taken along line 3A-3A in FIG. 3.

FIG. 4 is a partial top plan view of the lead frame panel array undergoing a die attach process.

FIG. 4A is a partial sectional side elevation view of the lead frame panel array taken along line 4A-4A in FIG. 4.

FIG. 5 is a partial top plan view of the lead frame panel array undergoing a wire bonding process.

FIG. 5A is a partial sectional side elevation view of the lead frame panel array taken along line 5A-5A in FIG. 5.

FIG. 6 is a partial top plan view of the lead frame panel array undergoing a molding process with a first mold portion engaging bottom sides of die attach pads.

FIG. 6A is a partial sectional side elevation view of the lead frame panel array taken along line 6A-6A in FIG. 6.

FIG. 6B is a partial sectional side elevation view of the lead frame panel array taken along line 6B-6B in FIG. 6.

FIG. 7 is a partial top plan view of the lead frame panel array undergoing the molding process with a second mold portion engaging top sides of lead bars and tie bars at the corners of the die attach pads.

FIG. 7A is a partial sectional side elevation view of the lead frame panel array taken along line 7A-7A in FIG. 7.

FIG. 7B is a partial sectional side elevation view of the lead frame panel array taken along line 7B-7B in FIG. 7.

FIG. 8 is a partial sectional top plan view of the lead frame panel array taken along line 8-8 of FIGS. 8A and 8B undergoing mold fill during the molding process.

FIG. 8A is a partial sectional side elevation view of the lead frame panel array taken along line 8A-8A in FIG. 8.

FIG. 8B is a partial sectional side elevation view of the lead frame panel array taken along line 8B-8B in FIG. 8.

FIG. 8C is a partial top plan view of the lead frame panel array after the molding process with the mold portions removed.

FIG. 9 is a partial top plan view of the lead frame panel array undergoing a lead trim process.

FIG. 9A is a partial sectional side elevation view of the lead frame panel array taken along line 9A-9A in FIG. 9.

FIG. 10 is a partial top plan view of the lead frame panel array undergoing a package separation process.

FIG. 10A is a partial sectional side elevation view of the lead frame panel array taken along line 10A-10A in FIG. 10.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means+/−10 percent of the stated value.

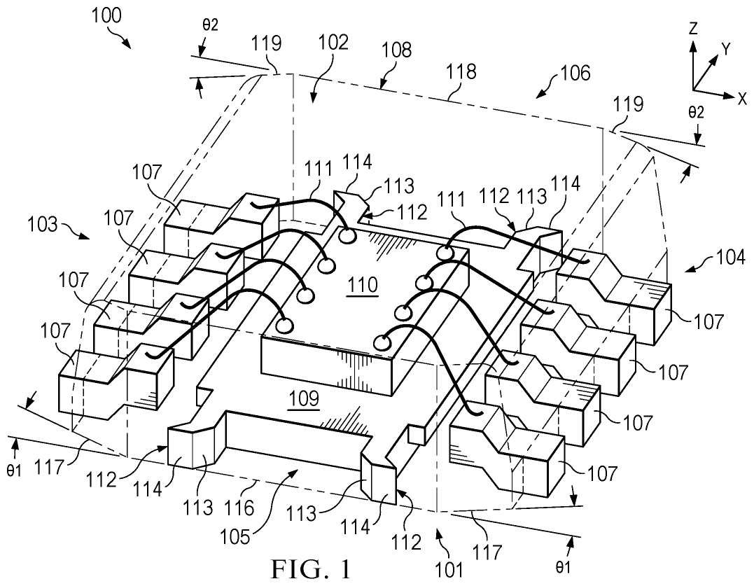

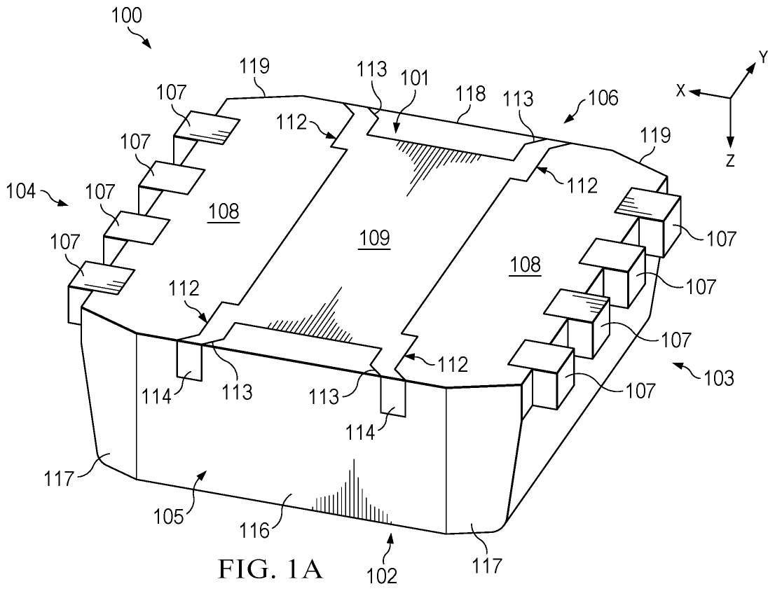

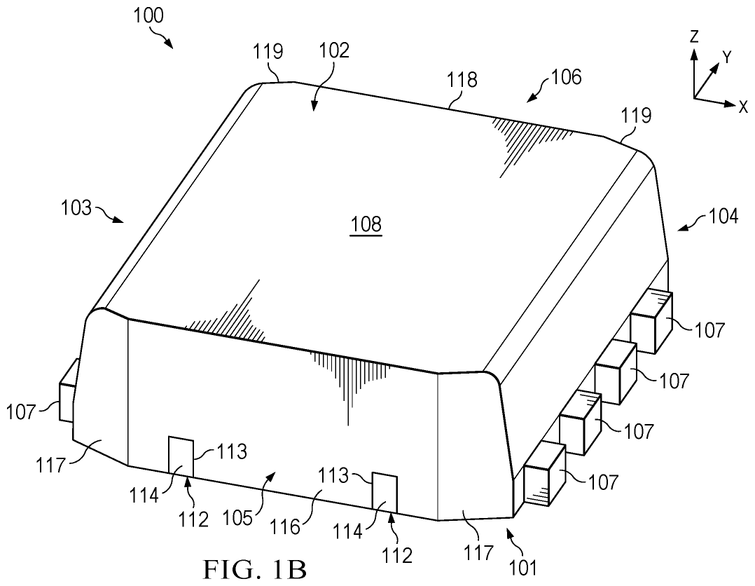

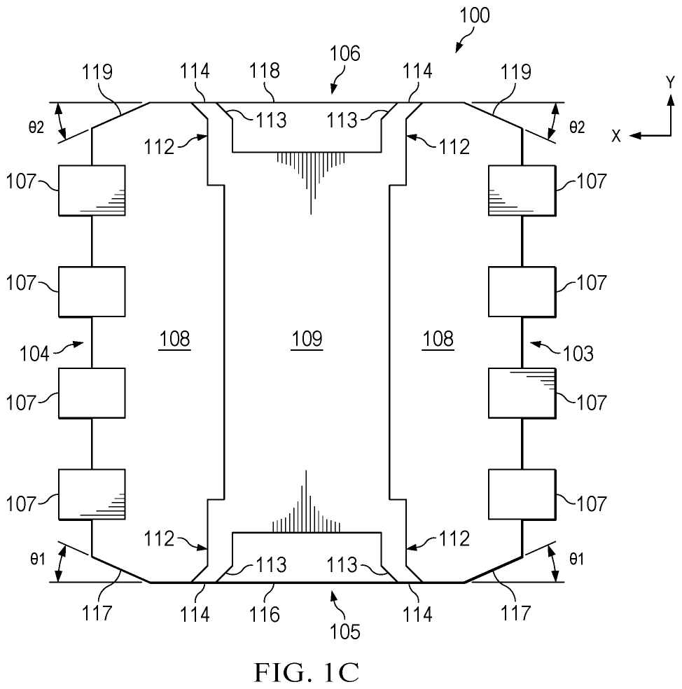

FIGS. 1-1C show an electronic device 100 with angled tie bars that extend from an exposed die attach pad and corner indents in a molded package structure. FIG. 1 shows a top perspective view illustrating internal details, FIG. 1A shows a bottom perspective view, FIG. 1B shows a top perspective external view, and FIG. 1C shows a bottom view of the electronic device 100. FIGS. 1-1C show an example electronic device 100 in an example position or orientation in a three-dimensional space with a first direction X, a perpendicular (orthogonal) second direction Y, and a third direction Z that is perpendicular (orthogonal) to the respective first and second directions X and Y, and structures or features along any two of these directions are orthogonal to one another.

The electronic device 100 has conductive metal leads 107 at least partially exposed outside a package structure 108, such as a molded plastic, and the electronic device has opposite first and second (e.g., bottom and top) sides 101 and 102, respectively, which are spaced apart from one another along the third direction Z. The package structure 108 and the electronic device 100 have laterally opposite third and fourth sides 103 and 104 spaced apart from one another along the first direction X, and opposite ends, referred to as fifth and sixth sides 105 and 106, that are spaced apart from one another along the second direction Y in the illustrated orientation.

The sides 101-106 in one example have substantially planar outer surfaces with indents in the fifth and sixth ends or sides 105 and 106. In other examples, one or more of the sides 101-106 have curves, angled features, or other non-planar surface features. As discussed further below, the example electronic device 100 has a die attach pad 109 (also referred to as a die pad) with a bottom side at least partially exposed along the first side 101 of the package structure 108 and includes unique tie bar and molded indent features in the package structure 108 to facilitate die pad clamping during molding to mitigate over-molding and associated mold flash. Moreover, the described examples can be fabricated in high density array panels using column mold cavities for cost reduction while providing mold clamping and holding of the die attach pad structures 109 to help avoid mold flash and facilitate operation of the exposed die attached pad 109 for thermal heat removal and/or to provide an electrical ground or reference connection to a host printed circuit board (not shown).

The electronic device 100 includes a semiconductor die 110 attached to a die attach pad 109, for example, using a die attach adhesive, solder connections, electrically conductive adhesive connections, etc. The package structure 108 encloses a portion of the semiconductor die 110 and a top and side portions of the die attach pad 109, and the first side 101 of the package structure 108 exposes a portion of the die attach pad 109 as best shown in FIG. 1A. The conductive leads 107 are positioned in rows along the respective third and fourth sides 103 and 104 of the package structure 108. The conductive leads 107 in the illustrated example have bottom sides exposed along the first side 101 of the package structure 108 and extend laterally outward from the respective sides 103 and 104 along the first direction X. Bond wires 111 form electrical connections between bond pads or other conductive features of the semiconductor die 110 and respective ones of the conductive leads 107.

The electronic device 100 also includes tie bars 112 that extend from the die attach pad 109 and having respective ends 114 exposed along the respective fifth and sixth sides 105 and 106 of the package structure 108. In the illustrated example, the bottom sides of the tie bars 112 are exposed along the first side 101 of the package structure 108. In other example, the tie bars are not exposed along the bottom first side 101 of the package structure 108. In certain implementations, the tie bars are angled. In the illustrated example, each tie bar 112 includes a first portion 112 that extends from a respective corner of the die attach pad 109 along the second direction Y, as well as a second portion 113 that extends from the first portion 112 to the respective end 114 at a non-zero angle to the second direction Y.

The fifth side 105 of the package structure 108 includes a first center portion 116 that extends in a first plane of the first and third directions X and Z, and indents 117 that extend to a respective one of the third and fourth sides 103 and 104 of the package structure 108. The sixth side 106 of the package structure 108 includes a second center portion 118 that extends in a second plane of the first and third directions X and Z, and indents 119 that extend to a respective one of the third and fourth sides 103 and 104 of the package structure 108. In one example, the indents 117 of the fifth side 105 extend at an angle θ1 of approximately 15 to 25 degrees to the first direction X, and the indents 119 of the sixth side 106 extend at an angle θ2 of approximately 15 to 25 degrees to the first direction X. In one example, the angles θ1 and θ2 are approximately equal, although not a requirement of all implementations. Angles θ1 and θ2 greater than 25 degrees can limit the amount of tie bar engagement with a mold portion during package molding, and thus increase the likelihood or over-molding and mold flash, whereas angles θ1 and θ2 less than 15 degrees can restrict mold flow during mold filling operations. In the illustrated example, each tie bar end 114 extends to and is coplanar (e.g., flush) with the respective center portion 116, 118 of the respective side 105, 106.

A first indent 117 of the fifth side 105 extends from the first center portion 116 to the third side 103 of the package structure 108 away from the first plane of the first and third directions X and Z and partially toward the second plane of the first and third directions X and Z. A second indent 117 of the fifth side 105 of the package structure 108 extends from the first center portion 116 to the fourth side 104 of the package structure 108 away from the first plane of the first and third directions X and Z and partially toward the second plane of the first and third directions X and Z. Along the sixth side 106 of the package structure 108, a first indent 119 extends from the second center portion 118 to the third side 103 of the package structure 108 away from the second plane of the first and third directions X and Z and partially toward the first plane of the first and third directions X and Z. A second indent 119 of the sixth side 106 extends from the second center portion 118 to the fourth side 104 of the package structure 108 away from the second plane of the first and third directions X and Z and partially toward the first plane of the first and third directions X and Z. In one example, the indents 117 and 119 have arcuate profiles. In this or another example, the indents 117 and 119 have concave profiles.

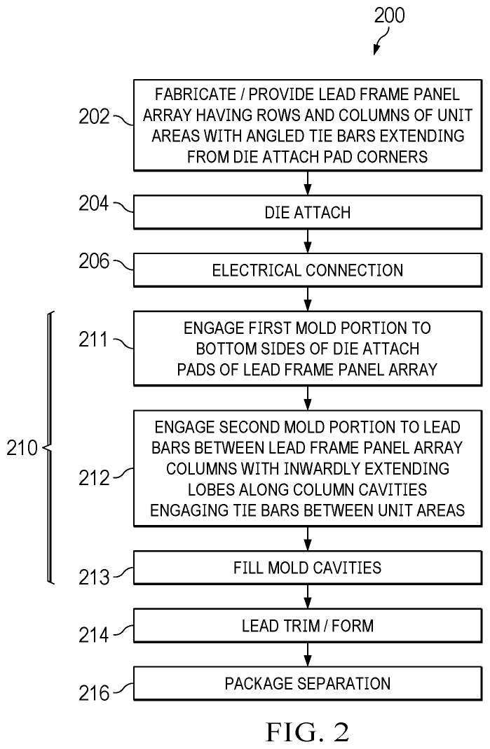

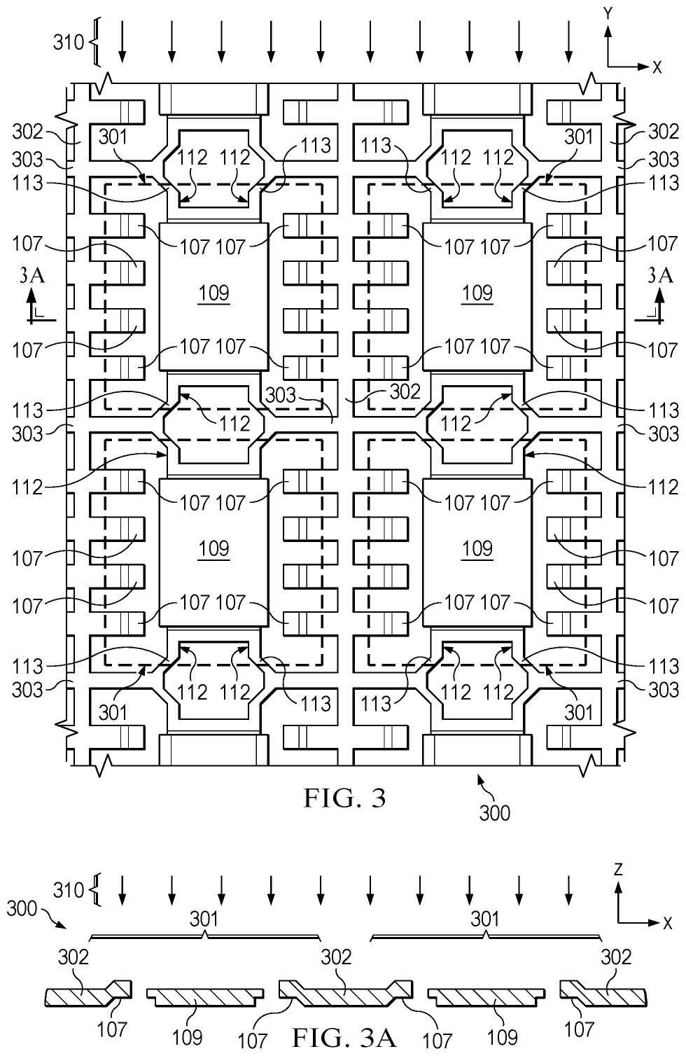

FIG. 2 shows a method 200 of fabricating an electronic device, and FIGS. 3-10A show the example electronic device 100 undergoing fabrication processing according to the method 200. The method 200 begins at 202 in FIG. 2 with fabricating or otherwise providing a lead frame panel array having rows and columns of unit areas (e.g., regions) with angled tie bars extending from die attach pad corners. FIGS. 3 and 3A show partial top and sectional side views of an example lead frame panel array 300 undergoing a fabrication process 310. The lead frame panel array 300 includes rows of unit areas 301 along a first direction X and columns of unit areas 301 along an orthogonal second direction Y.

In one example, the lead frame panel array 300 is or includes copper, aluminum or other conductive metal, and is formed by the process 310 using suitable processing techniques, such as stamping, etching, saw or laser cutting, etc. or combinations thereof. The lead frame panel array 300 includes a contiguous metal structure that defines the rows and columns of the unit areas 301, lead bars 302 that extend along the second direction Y between adjacent columns of the unit areas 301 and connecting bars 303 that extend along the first direction X from respective ones of the lead bars 302. The respective unit areas 301 include a die attach pad 109, conductive leads 107, and tie bars 112. The leads 107 are positioned along opposite sides of the die attach pad 109 in the individual unit areas 301, and the leads 107 are spaced apart from the corresponding die attach pad 109 along the first direction X. The conductive leads 107 extend along the first direction X from a respective one of the lead bars 302 toward the corresponding die attach pad 109.

The individual tie bars 112 include the first portion that extends outward along the second direction Y from a respective corner of the corresponding die attach pad 109, and a second portion 113 that extends from the first portion 112 to a respective one of the connecting bars 303. This provides a structure useful for application of downward force to the die attach pad 109 by an upper mold portion pushing down on the tie bars, while providing clearance for suitable mold filling of column cavities during device fabrication.

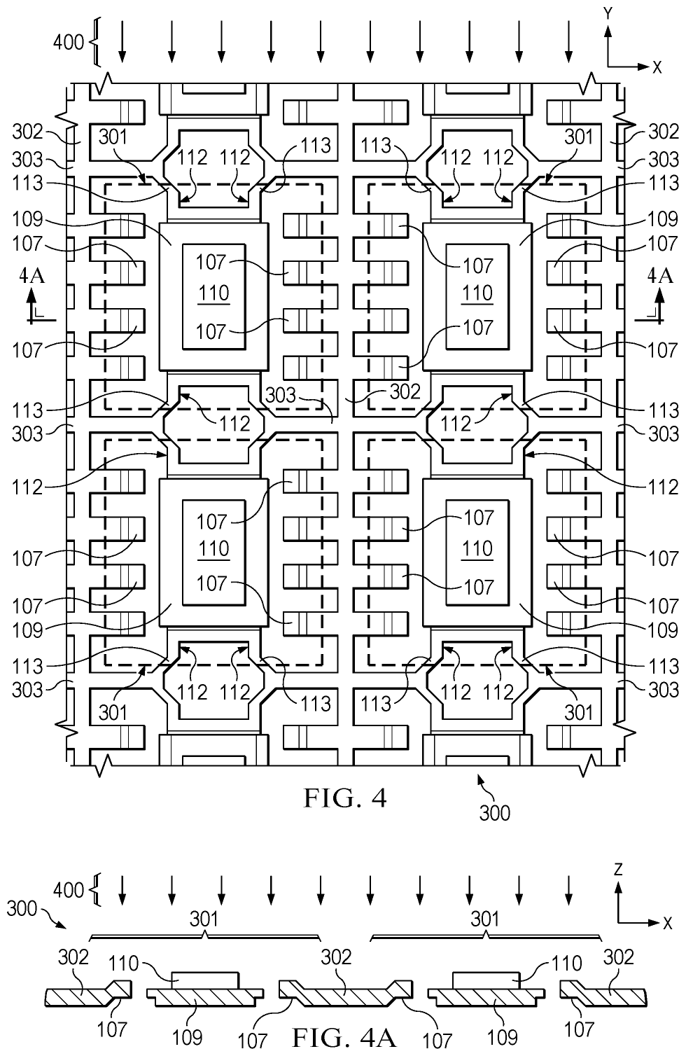

The method 200 continues at 204 in FIG. 2 with die attach processing. FIGS. 4 and 4A show partial top and sectional side views of one example, in which a die attach process 400 is performed that attaches the semiconductor die 110 to the die attach pad in each of the unit areas 301 of the lead frame panel array 300, for example, using a die attach adhesive, solder connections, electrically conductive adhesive connections, etc.

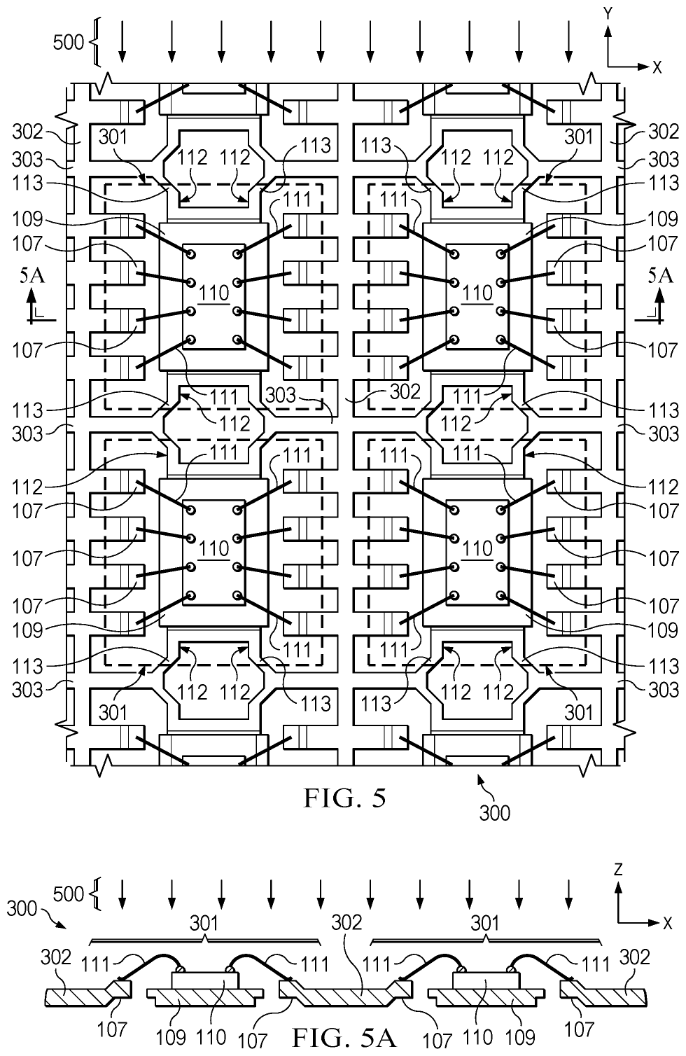

At 206 in FIG. 2, the method 200 continues with electrical connection processing. FIGS. 5 and 5A show one example, in which a wire bonding electrical connection process 500 is performed that forms bond wires 111 that form electrical connections between bond pads or other conductive features of the semiconductor die 110 and respective ones of the conductive leads 107.

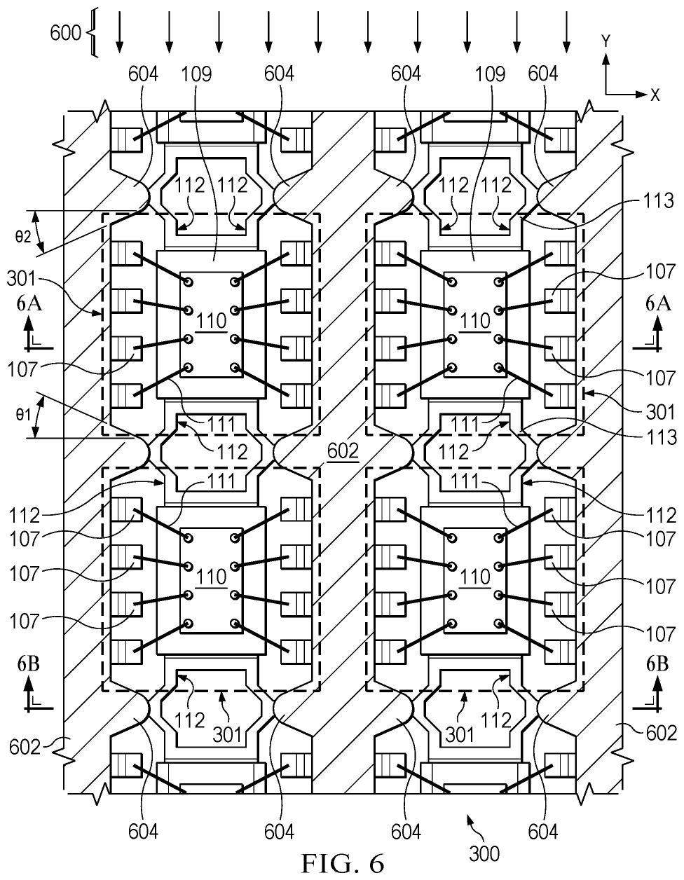

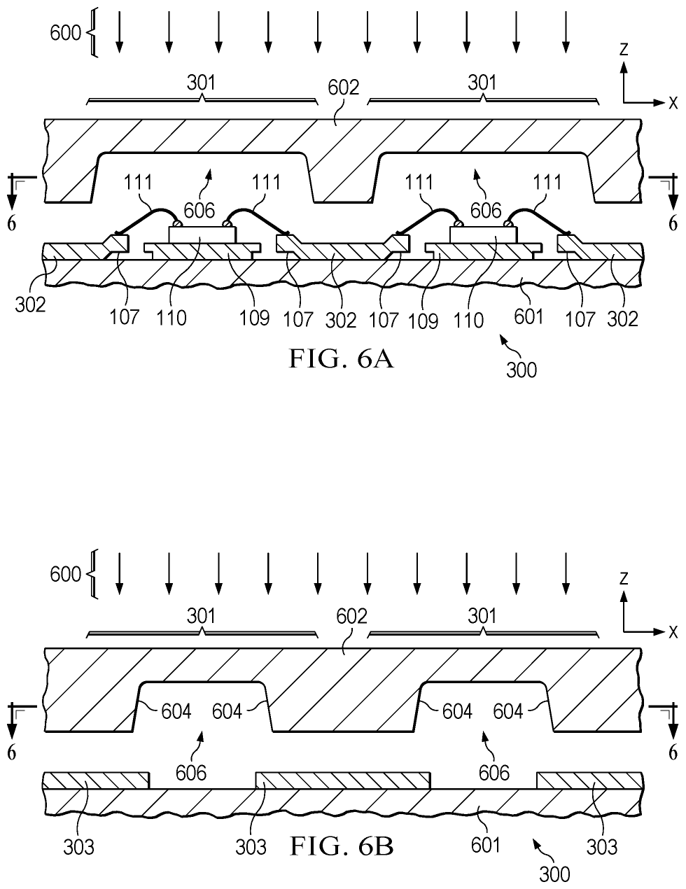

Molding processing is performed at 210 in FIG. 2. FIGS. 6-6B show an example mold 601, 602 according to another aspect, which can be used in the molding processing at 210 of the method 200. The mold in which example includes a first mold potion 601 configured to engage bottom sides of the die attach pads 120 in respective unit areas 301 of the lead frame panel array 300 having rows and columns of the unit areas 301, as well as an upper or second mold portion 602 configured to engage lead bars 302 between columns of the lead frame panel array 300. The second mold portion 602 includes lobes 604 extending inwardly along column cavities 606 of the second mold portion 602 and the lobes 604 are configured to engage the tie bars 112 of the lead frame panel array 300 between the unit areas 301.

In the illustrated example, the upper mold lobes 604 are configured to extend at the angles θ1, θ2 of approximately 15 to 25 degrees to the first (row) direction X of the lead frame panel array 300, as best shown in FIG. 6, where the angles θ1, θ2 of the mold lobes 604 generally correspond to the angles θ1, θ2 of the electronic device end indents 117 and 119 described above in connection with FIGS. 1 and 1C. Angles θ1 and θ2 greater than 25 degrees can limit the amount of tie bar engagement with a mold portion during package molding, and thus increase the likelihood or over-molding and mold flash, whereas angles θ1 and θ2 less than 15 degrees can restrict mold flow during mold filling operations.

As further shown in FIGS. 6 and 6B, moreover, the lobes 604 in one example extend inward into the column cavities 606 to approximately align with lateral edges of the die attach pads 120 of the lead frame panel array 300. Lesser amounts of lateral extent of the lobes 604 inward into the corresponding column cavities 606 can limit the amount of tie bar engagement with a mold portion during package molding, and greater lateral extent of the lobes 604 inward into the corresponding column cavities 606 can restrict mold flow during mold filling operations.

The mold processing at 210 in FIG. 2 includes engaging a first (e.g., bottom or lower) mold portion to the bottom sides of the die attach pads at 211. FIGS. 6-6B show one example, in which the first mold potion 601 is engaged by a mold engagement process 600 to the bottom sides of the die attach pads 120 in respective unit areas 301 of the lead frame panel array 300.

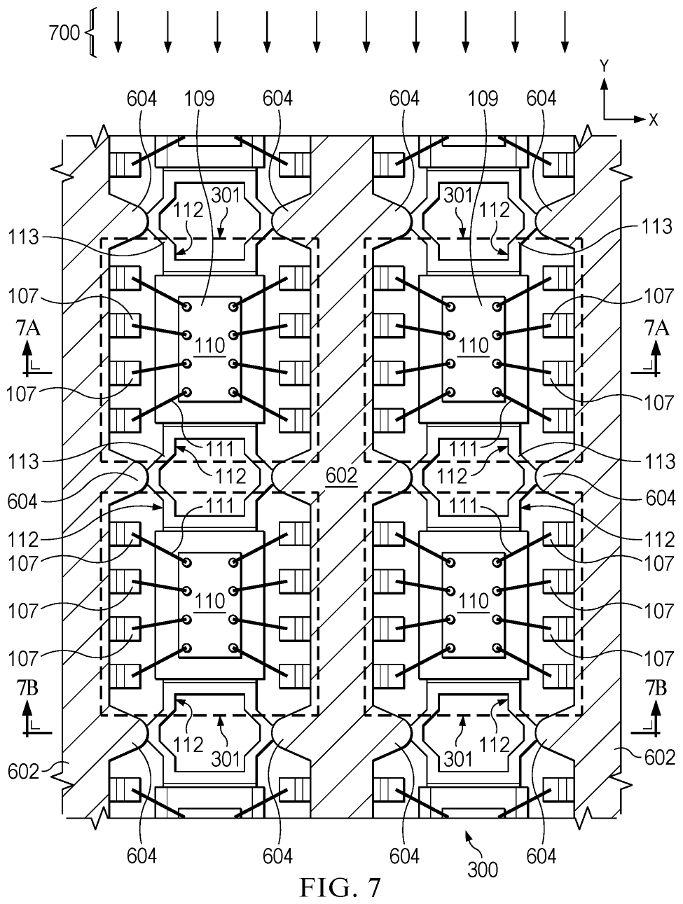

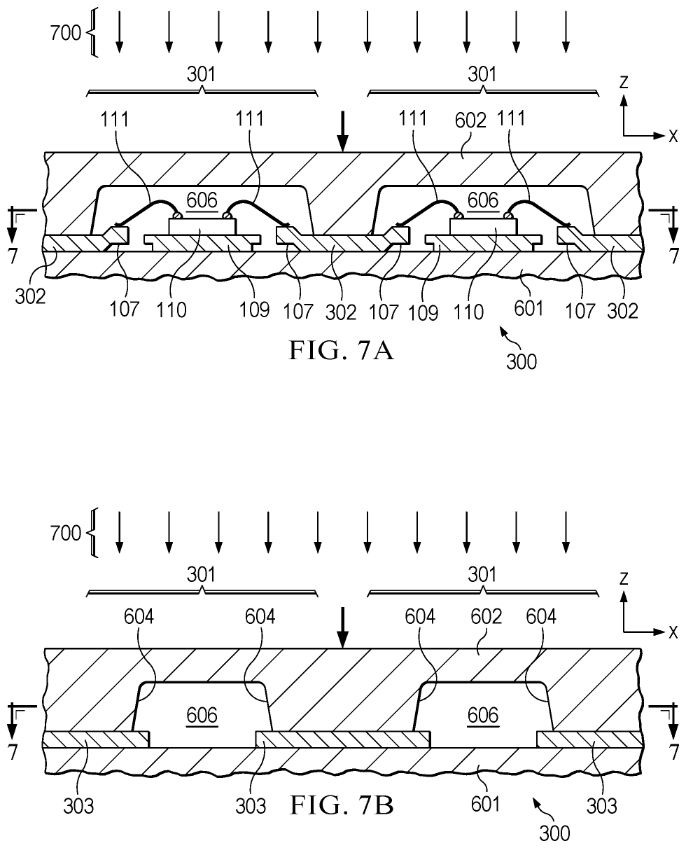

At 212 in FIG. 2, the molding processing also includes engaging the second (e.g., top or upper) mold portion 602 to the lead bars between the array columns and engaging lobes of the upper mold portion to the tie bars of the lead frame panel assembly. FIGS. 7-7B show one example, in which a mold closure process 700 is performed that moves the second mold portion 602 downward along a direction indicated by arrows in FIGS. 7A and 7B to engage the second mold portion 602 to the lead bars 302 between columns of the lead frame panel array 300 with the lobes 604 of the second mold portion 602 extending inwardly along column cavities 606 of the second mold portion 602 and engaging the tie bars 112 of the lead frame panel array 300 between the unit areas 301.

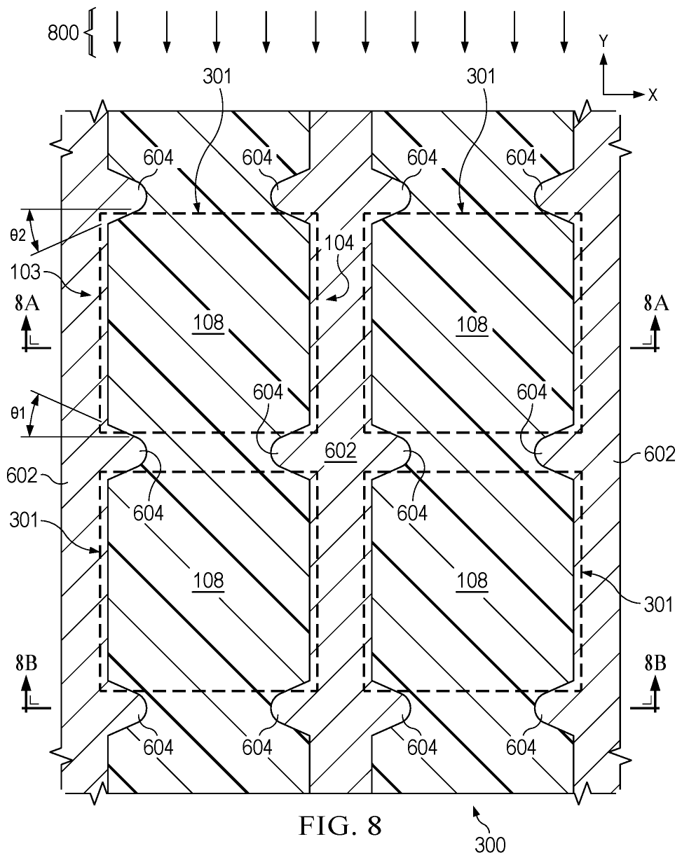

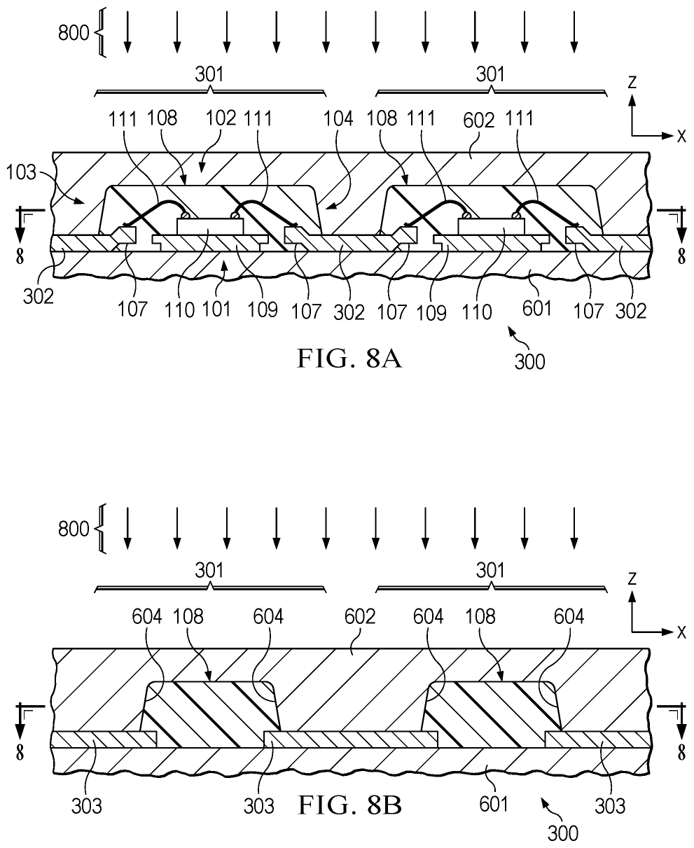

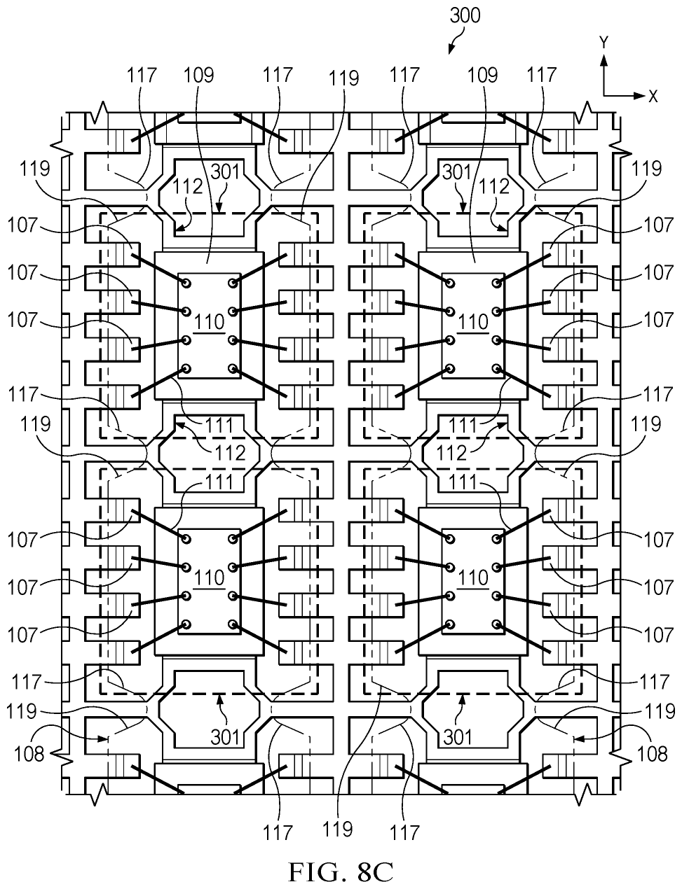

The mold processing at 210 continues at 213 in FIG. 2, with mold filling to fill the mold cavities. FIGS. 8-8C show one example, in which a mold filling process 800 is performed that fills the column cavities 606 of the second mold portion 602 to form the package structures 108 along the column cavities 606 of the second mold portion 602 with indents 117 and 119 of the package structures 108 in corners of the unit areas 301 of the lead frame panel array 300. FIG. 8C shows top view of the lead frame panel array after the molding process 800 is completed and the mold portions 601 and 602 have been removed. As shown in FIG. 8C, the molded package structure 108 includes portions of the above described indents 117 and 119 of the package structures 108 with arcuate and concave profiles, and the indents 117 and 119 of the package structures 108 extend at the respective angles θ1 and θ2 of approximately 15 to 25 degrees to the first (row) direction X of the lead frame panel array 300.

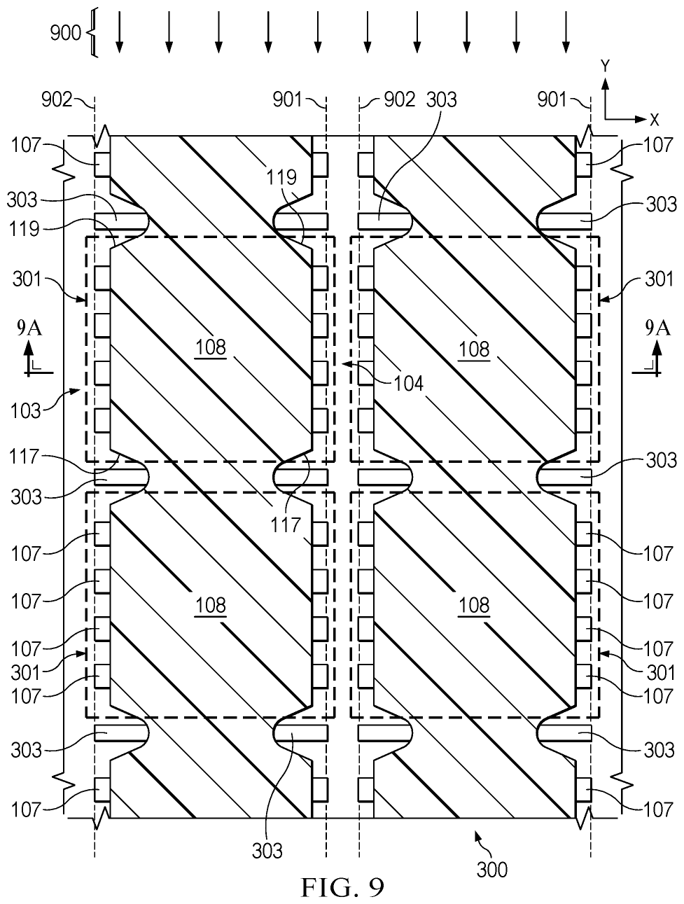

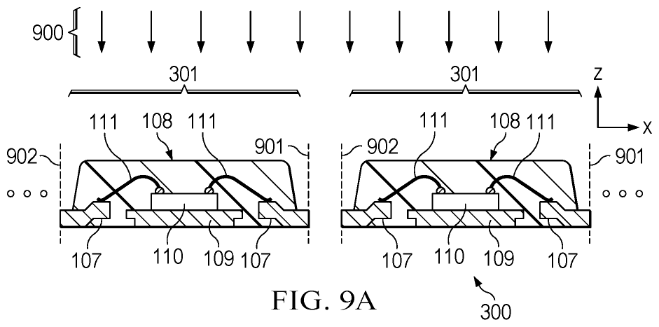

The method 200 continues at 214 in FIG. 2 with trimming the leads 107 between columns of the lead frame panel array 300. FIGS. 9 and 9A show partial top and sectional side views of one example, in which a lead trimming process 900 is performed that cuts or otherwise separates the leads 107 along the second direction between adjacent array columns. In one example, the lead trimming process 900 is a double cut process with first cuts made along lines 901 and second cuts made along lines 902, for example, to extend cutting tool lifetime and/or reduce power by cutting only through the laterally extending leads 107 and avoiding cutting directly through the lead bars 302. In one example, the lead trimming process 900 is a saw cutting process. In another example, the lead trimming process 900 is a laser cutting process. The process 900 forms the cut ends of the conductive leads 107 of the finished electronic device. In one example, the process 900 also includes optional lead forming operations (not shown), for example, using dies and other apparatus to form bends or other features of the finished conductive leads 107.

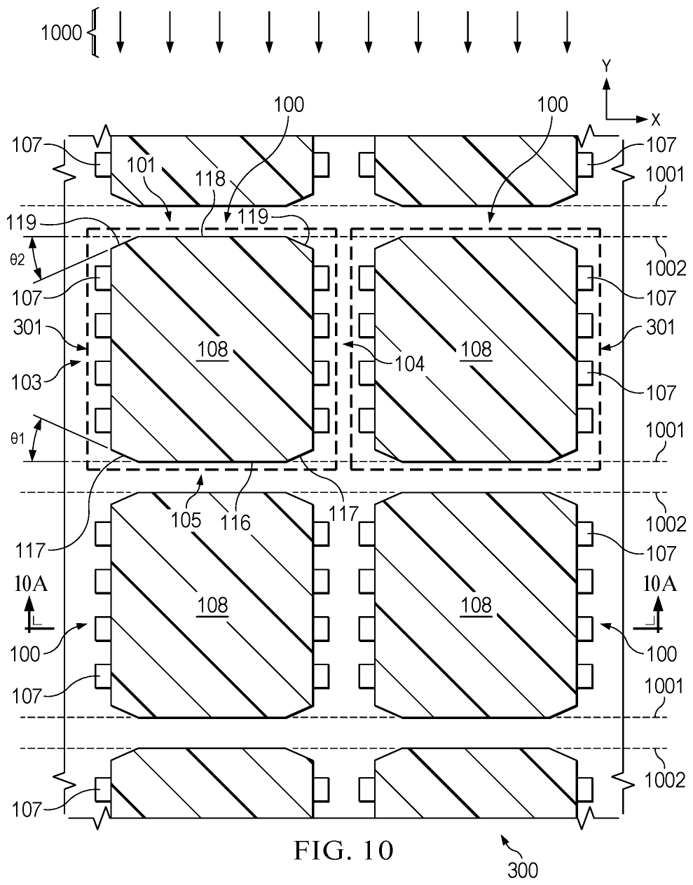

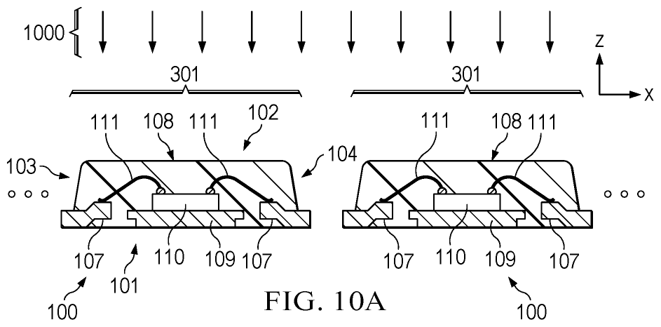

The method 200 also includes package separation at 216 in FIG. 2. FIGS. 10 and 10A show partial top and sectional side views of one example, in which a package separation process 1000 is performed that cuts through the tie bars 112 between the unit areas 301 along the first or row direction X of the lead frame panel array 300 to separate packaged electronic devices 100 from the lead frame panel array 300. In one example, the package separation process 1000 is a double cut process with first cuts made along lines 1001 and second cuts made along lines 1002, for example, to extend cutting tool lifetime and/or reduce power by cutting only through the second portions 113 of the tie bars 112 and avoiding cutting directly through the connecting bars 303. The package separation process 1000 creates the planar center portions 116 and 118 of the package ends along the respective fifth and sixth sides 105 and 106 (FIGS. 1-1C), including cutting the ends 114 of the angled tie bar portions 113 flush (e.g., coplanar) with the respective center portions 116 and 118, and the package separation process 1000 leaves the remaining arcuate corner indents 117 and 119 extending from the respective at the device package corner center portions 116 and 118 to the corresponding lateral sides 103 and 104.

The described examples provide solutions to mitigate or avoid over-molding and mold flash problems in electronic device 100 having exposed die attach pads 109, and the described solutions are amenable to use with molds having column mold cavities 606 to facilitate low cost manufacture of large high density lead frame panel arrays with high units per sheet. The described lead frame panel arrays 300 and mold tooling facilitate improved clamping of the tie bars by downward force of the upper mold portion 602 to fix the die attach pads 109 in place during mold filling processes 800 to reduce the chances of over-molding through mold compound leakage and mold flash formation.

Modifications are possible in the described examples, and other implementations are possible, within the scope of the claims.

What is claimed is:

1. An electronic device, comprising:
a semiconductor die attached to a die attach pad;
a package structure having opposite first and second sides, opposite third and fourth sides spaced apart from one another along a first direction, and opposite fifth and sixth sides spaced apart from one another along a second direction that is orthogonal to the first direction, the package structure enclosing a portion of the semiconductor die and a portion of the die attach pad, and the first side of the package structure exposing a portion of the die attach pad;
conductive leads positioned along opposite third and fourth sides of the package structure, the conductive leads having sides exposed along the first side of the package structure; and
tie bars extending from the die attach pad and having respective ends exposed along the respective fifth and sixth sides of the package structure;
the fifth and sixth sides of the package structure each having individual indents that extend to a respective one of the third and fourth sides of the package structure.

2. The electronic device of claim 1, wherein:
the fifth side of the package structure includes a first center portion that extends in a first plane of the first direction and a third direction that is orthogonal to the first and second directions;
the sixth side of the package structure includes a second center portion that extends in a second plane of the first and third directions;
a first indent of the fifth side of the package structure extends from the first center portion to the third side of the package structure away from the first plane of the first and third directions and partially toward the second plane of the first and third directions;
a second indent of the fifth side of the package structure extends from the first center portion to the fourth side of the package structure away from the first plane of the first and third directions and partially toward the second plane of the first and third directions;
a first indent of the sixth side of the package structure extends from the second center portion to the third side of the package structure away from the second plane of the first and third directions and partially toward the first plane of the first and third directions; and
a second indent of the sixth side of the package structure extends from the second center portion to the fourth side of the package structure away from the second plane of the first and third directions and partially toward the first plane of the first and third directions.

3. The electronic device of claim 2, wherein the indents of the fifth and sixth sides of the package structure have arcuate profiles.

4. The electronic device of claim 2, wherein the indents of the fifth and sixth sides of the package structure have concave profiles.

5. The electronic device of claim 3, wherein each tie bar includes a first portion that extends from a respective corner of the die attach pad along the second direction, and a second portion that extends from the first portion to the respective end at an angle to the second direction.

6. The electronic device of claim 3, wherein each tie bar end extends to and is coplanar with the center portion of the respective one of the fifth and sixth sides.

7. The electronic device of claim 3, wherein the indents extend at an angle of approximately 15 to 25 degrees to the first direction.

8. The electronic device of claim 2, wherein each tie bar includes a first portion that extends from a respective corner of the die attach pad along the second direction, and a second portion that extends from the first portion to the respective end at an angle to the second direction.

9. The electronic device of claim 2, wherein each tie bar end extends to and is coplanar with the center portion of the respective one of the fifth and sixth sides.

10. The electronic device of claim 2, wherein the indents extend at an angle of approximately 15 to 25 degrees to the first direction.

11. The electronic device of claim 1, wherein the indents extend at an angle of approximately 15 to 25 degrees to the first direction.

12. A method of fabricating an electronic device, the method comprising:
engaging a first mold potion to bottom sides of die attach pads in respective unit areas of a lead frame panel array having rows and columns of the unit areas;
engaging a second mold portion to lead bars between columns of the lead frame panel array with lobes of the second mold portion extending inwardly along column cavities of the second mold portion and engaging tie bars of the lead frame panel array between the unit areas;
filling the column cavities of the second mold portion to form package structures along the column cavities of the second mold portion with indents of the package structures in corners of the unit areas of the lead frame panel array;
trimming leads between columns of the lead frame panel array; and
cutting through the tie bars between the unit areas along a row direction of the lead frame panel array to separate packaged electronic devices from the lead frame panel array.

13. The method of claim 12, wherein the lobes extend inward into the column cavities to approximately align with lateral edges of the die attach pads.

14. The method of claim 12, wherein the indents of the package structures have arcuate profiles.

15. The method of claim 14, wherein the indents of the package structures have concave profiles.

16. The method of claim 12, wherein the indents of the package structures extend at an angle of approximately 15 to 25 degrees to a row direction of the lead frame panel array.

17. A lead frame panel array, comprising a contiguous metal structure that defines rows of unit areas along a first direction and columns of the unit areas along an orthogonal second direction, lead bars extending along the second direction between adjacent columns of the unit areas, and connecting bars extending along the first direction from respective ones of the lead bars, respective unit areas including:
a die attach pad;
leads positioned along opposite sides of the die attach pad and spaced apart from the die attach pad along the first direction, the leads extending along the first direction from a respective one of the lead bars toward the die attach pad; and
tie bars individually including a first portion that extends outward along the second direction from a respective corner of the die attach pad, and a second portion that extends from the first portion to a respective one of the connecting bars.

18. A mold, comprising:
a first mold potion configured to engage bottom sides of die attach pads in respective unit areas of a lead frame panel array having rows and columns of the unit areas; and
a second mold portion configured to engage lead bars between columns of the lead frame panel array, the second mold portion including lobes extending inwardly along column cavities of the second mold portion and configured to engage tie bars of the lead frame panel array between the unit areas.

19. The mold of claim 18, wherein the lobes are configured to extend at an angle of approximately 15 to 25 degrees to a row direction of the lead frame panel array.

20. The mold of claim 18, wherein the lobes extend inward into the column cavities to approximately align with lateral edges of the die attach pads of the lead frame panel array.
